(19) United States
(12) Patent Application Publication
(10) Pub. No.: US 2012/0085574 A1
(43) Pub. Date: Apr. 12, 2012

(54) Heat radiating substrate and method of manufacturing the same

(75) Inventors: Ji Hyun Park, Seoul (KR); Tae Hoon Kim, Suwon-si (KR); Sang Hyun Shin, Suwon-si (KR); Ki Ho Seo, Suwon-si (KR); Cheol Ho Heo, Busan (KR); Young Ki Lee, Hwaseong-si (KR)

(73) Assignee: SAMSUNG ELECTRO-MECHANICS CO., LTD., Suwon (KR)

(21) Appl. No.: 13/064,364

(22) Filed: Mar. 21, 2011

(30) Foreign Application Priority Data
Oct. 12, 2010 (KR) 10-2010-0099370

(51) Int. Cl. H05K 1/14; H05K 3/42

(52) U.S. Cl. 174/264; 29/852

(57) ABSTRACT

Provided are a heat radiating substrate and a method of manufacturing the same. The heat radiating substrate includes a substrate having a via-hole, an anode oxide layer formed on the entire surface of the substrate having the via-hole through an anodizing process, a first circuit pattern formed on the substrate on which the anode oxide layer is formed, and a second circuit pattern formed at a lower part of the via-hole to be connected to the via-hole. Therefore, it is possible to simplify a circuit forming process and readily manufacture the heat radiating substrate by applying a metal anodic bonding process, without using a conventional adhesion layer and metal seed when the heat radiating substrate is manufactured.

### CROSS-REFERENCE TO RELATED APPLICATIONS

This application claims the benefit under 35 U.S.C. Section 119 of Korean Patent Application Serial No. 10-2010-0099370, entitled “Heat Radiating Substrate And Method Of Manufacturing The Same”, filed on Oct. 12, 2010, which is hereby incorporated by reference in its entirety into this application.”

### BACKGROUND OF THE INVENTION

1. Field of the Invention

The present invention relates to a heat radiating substrate and a method of manufacturing the same, and more particularly, to a heat radiating substrate and a method of manufacturing the same that are capable of applying an aluminum anode oxide layer upon manufacture of a substrate to improve radiating characteristics.

2. Description of the Related Art

In recent times, use of electronic parts is being increased in automobile and other industrial fields, and so on. Moreover, with progress of multi-function and miniaturization, a large number of parts are integrated on a small area of substrate. Accordingly, heat generated due to driving of electronic parts affects performance of the electronic parts.

Due to the above problems, provision of a heat radiating system in a substrate manufacturing field to prevent reduction in performance of electronic parts becomes an important issue.

As shown in FIG. 1, a conventional multi-layered aluminum substrate includes an aluminum substrate 11, an insulating layer 13, an adhesion layer 15, and a copper layer 17. First, the insulating layer is formed on the aluminum substrate using an anode oxidation method, and then, a copper film is adhered thereto using adhesive such as epoxy, resin, or the like. At this time, if necessary, a plating or coating process may be performed for both-side conduction. While a conventional FR4 or GETEK substrate has good insulation, the substrate has low thermal conductivity that cannot be used for the purpose of heat radiation.

Meanwhile, in manufacturing the substrate, when a circuit part is adhered to an aluminum substrate or a metal substrate using adhesive, heat radiation characteristics may decrease. In addition, when a metal seed is used, it is difficult to remove the metal seed.

### SUMMARY OF THE INVENTION

The present invention has been invented in order to overcome the above-described problems and it is, therefore, an object of the present invention to provide a heat radiating substrate and a method of manufacturing the same that are capable of applying an aluminum anode oxide layer to improve heat radiating characteristics.

In accordance with one aspect of the present invention to achieve the object, there is provided a method of manufacturing a heat radiating substrate including: a) forming a via-hole in a substrate; b) forming an anode oxide layer on the entire surface of the substrate in which the via-hole is formed; c) adhering an aluminum plate for forming an upper circuit onto the substrate, on which the anode oxide layer is formed, through anodic bonding; d) patterning the aluminum plate to form a first circuit pattern; and e) forming a second circuit pattern on a via-filling part of the via-hole and a lower part in which the via-hole is formed.

In addition, the substrate may be formed of an aluminum material.

Further, in the step a), the via-hole may be formed by a mechanical machining process such as drilling or punching, or a chemical process such as wet etching.

Furthermore, in the step a), the via-hole may be formed to at least two or more.

In addition, in the step b), the anode oxide layer may be formed through an anodizing process.

Further, the anode oxide layer may be formed of Al₂O₃.

Furthermore, in the anodic bonding of the step c), a pressure may be 500 mbar to 4000 mbar, a voltage may be 500V to 1500V, and a temperature may be 550° C. or less.

In addition, in the step e), the via-filling part and the second circuit pattern may be formed of metal paste or conductive paste.

In accordance with another aspect of the present invention to achieve the object, there is provided a heat radiating substrate including: a substrate having a via-hole; an anode oxide layer formed on the entire surface of the substrate having the via-hole through an anodizing process; a first circuit pattern formed on the substrate on which the anode oxide layer is formed; and a second circuit pattern formed at a lower part of the via-hole to be connected to the via-hole, wherein the first circuit pattern is adhered to the substrate, on which the anode oxide layer is formed, through anodic bonding.

In addition, the via-hole may be formed to at least two or more.

Further, the via-hole may be filled with metal paste or conductive paste.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a conventional aluminum single layer substrate;

FIG. 2 is a cross-sectional view showing configuration of a heat radiating substrate in accordance with an exemplary embodiment of the present invention; and

FIGS. 3 to 7 are cross-sectional views for sequentially explaining a method of manufacturing a heat radiating substrate in accordance with an exemplary embodiment of the present invention.

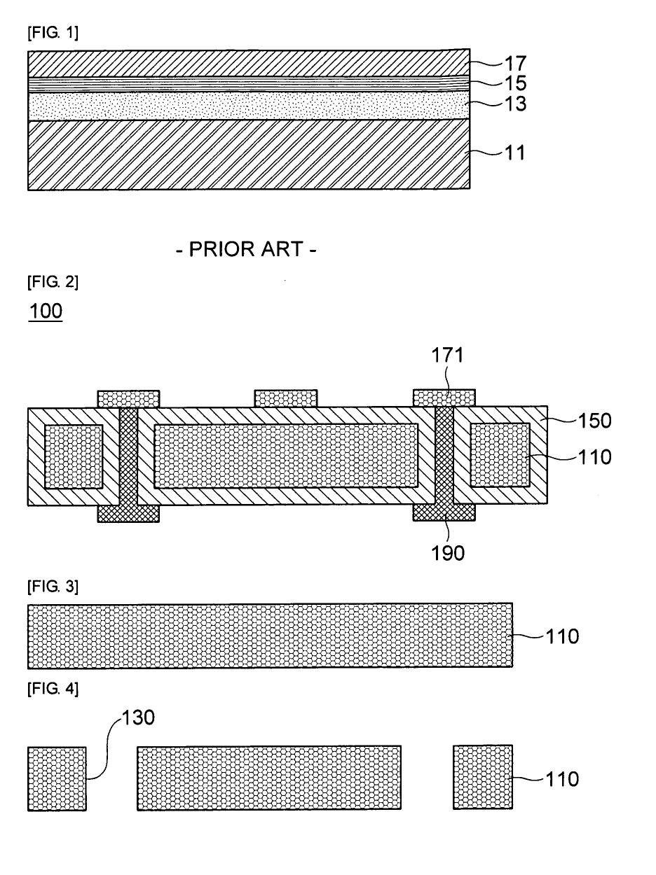

### DETAILED DESCRIPTION OF THE PREFERABLE EMBODIMENTS

Hereinafter, embodiments of the present invention will be described in detail with reference to the accompanying drawings. The following embodiments are provided as examples to fully convey the spirit of the invention to those skilled in the art.

Descriptions of well-known components and processing techniques are omitted so as not to unnecessarily obscure the embodiments of the present invention. The following terms are defined in consideration of functions of the present invention and may be changed according to users or operator's intentions or customs. Thus, the terms shall be defined based on the contents described throughout the specification.

Therefore, the technical sprit of the present invention should be defined by the attached claims, not being construed as limited to the embodiments set forth herein and may be embodied in different forms.

FIG. 2 is a cross-sectional view showing configuration of a heat radiating substrate in accordance with an exemplary embodiment of the present invention.

As shown in FIG. 2, a heat radiating substrate 100 may include a substrate 110, an anode oxide layer 150, a first circuit pattern 171, and a second circuit pattern 190.

More specifically, the substrate 110 may be formed to have a via-hole 130 (see FIG. 4).

Here, the via-hole 130 may be formed by applying both a mechanical machining method such as drilling, punching, and so on, and a chemical process such as wet etching, and so on.

In addition, the via-hole 130 may be formed to at least two or more.

Further, as shown in FIG. 2, the via-hole 130 may be filled with metal paste or conductive paste.

The anode oxide layer 150 may be formed on the entire surface of the substrate 110 having the via-hole 130.

As shown in FIG. 2, the anode oxide layer 150 may be formed at a region, in which the via-hole 130 is formed, as well as upper, lower and side surfaces of the substrate 110.

The first circuit pattern 171 may be formed on the substrate, on which the anode oxide layer is formed, through an anodizing process.

In addition, the first circuit pattern 171 may be adhered to the substrate, on which the anode oxide layer is formed, through an anodic bonding process.

At this time, as an anode is adhered between the insulating layer having the anode oxide layer 150 formed on the substrate 110 through anodizing process (the substrate on which the anode oxide layer is formed) and an aluminum or metal substrate, reduction in heat radiating characteristics due to the adhesive or metal seed applied to adhere the conventional substrate and the circuit layer may be solved.

The second circuit pattern 190 may be formed at a lower part of the via-hole 130 to be connected to the via-hole 130.

As shown in FIG. 2, the second circuit pattern 190 may be disposed at the lower part of the via-hole 130 to be connected to the metal paste or conductive paste filled in the via-hole 130.

Hereinafter, a method of manufacturing a heat radiating substrate in accordance with an exemplary embodiment of the present invention will be sequentially described with reference to FIGS. 3 to 7.

First, as shown in FIGS. 3 and 4, a via-hole 130 may be formed in a substrate 110.

Here, the substrate 110 may be formed of an aluminum material.

In addition, the via-hole 130 may be formed by applying both a mechanical machining method such as drilling, punching, and so on, and a chemical process such as wet etching, and so on.

Further, the via-hole may be formed to at least two or more.

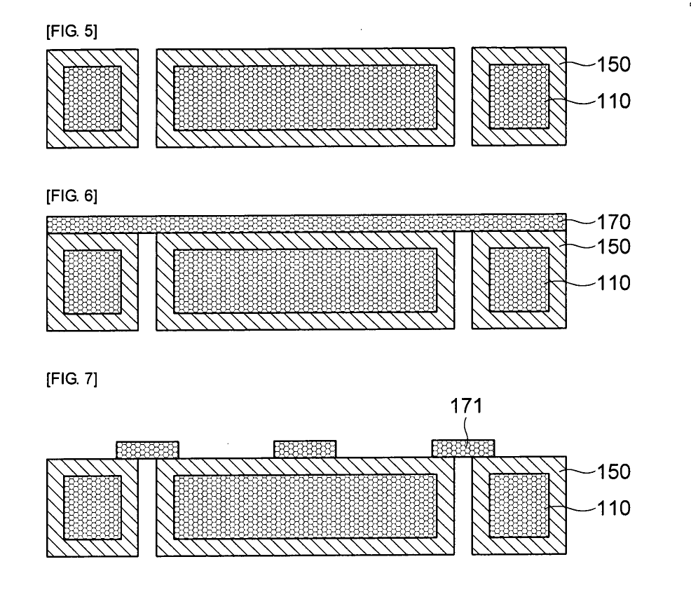

As shown in FIG. 5, an anode oxide layer 150 may be formed on the entire surface of the substrate 110 in which the via-hole 130 is formed.

Here, the anode oxide layer 150 may be formed through an anodizing process. In addition, the anode oxide layer may be formed of Al₂O₃.

Meanwhile, before forming the anode oxide layer, surface treatment for oxidation treatment of the electrode may be performed. The surface treatment may be performed by both of acid- and alkali-based material.

In addition, as shown in FIG. 6, an aluminum plate 170 for forming an upper circuit may be adhered onto the substrate on which the anode oxide layer 150 through anodic bonding.

Here, the anodic bonding may be performed under the condition that a pressure is 500 mbar to 4000 mbar, a voltage is 500V to 1500V, and a temperature is 550° C. or less. In addition, according to an operator's necessity, a main bonding process may be performed after a pre-bonding process.

Meanwhile, anode adhesion between the insulating layer on which the anode oxide layer 150 is formed on the substrate 110 through the anodizing process and an aluminum or metal substrate may be performed to prevent reduction in heat radiating characteristics.

As shown in FIG. 7, the aluminum plate 170 may be patterned to form a first circuit pattern 171

Meanwhile, according to an operator's necessity, sequence of the processes of FIGS. 6 and 7 may be changed so that the first circuit pattern may be formed first, and then, the anodic bonding process may be performed.

A second circuit pattern 190 may be formed on a via-filling part of the via-hole 130 and the lower part in which the via-hole 130 is formed.

Here, the via-filling part and the lower pattern may be formed of metal paste or conductive paste.

As can be seen from the foregoing, a heat radiating substrate and a method of manufacturing the same in accordance with the present invention can simplify a circuit forming process and readily manufacture the heat radiating substrate by applying a metal anodic bonding process, without using a conventional adhesion layer and metal seed when the heat radiating substrate is manufactured.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A method of manufacturing a heat radiating substrate comprising:
forming a via-hole in a substrate;
forming an anode oxide layer on the entire surface of the substrate in which the via-hole is formed;
adhering an aluminum plate for forming an upper circuit onto the substrate, on which the anode oxide layer is formed, through anodic bonding;
patterning the aluminum plate to form a first circuit pattern; and
forming a second circuit pattern on a via-filling part of the via-hole and a lower part in which the via-hole is formed.

2. The method of manufacturing a heat radiating substrate according to claim 1, wherein the substrate is formed of an aluminum material.

3. The method of manufacturing a heat radiating substrate according to claim 1, wherein, in the forming a via-hole, the via-hole is formed by a mechanical machining process such as drilling or punching, or a chemical process such as wet etching.

4. The method of manufacturing a heat radiating substrate according to claim 1, wherein, in the forming a via-hole, the via-hole is formed to at least two or more.

5. The method of manufacturing a heat radiating substrate according to claim 1, wherein, in the forming an anode oxide layer, the anode oxide layer is formed through an anodizing process.

6. The method of manufacturing a heat radiating substrate according to claim 5, wherein the anode oxide layer is formed of Al₂O₃.

7. The method of manufacturing a heat radiating substrate according to claim 1, wherein, in the anodic bonding of the adhering an aluminum plate, a pressure is 500 mbar to 4000 mbar, a voltage is 500V to 1500V, and a temperature is 550° C. or less.

8. The method of manufacturing a heat radiating substrate according to claim 1, wherein, in the forming a second circuit pattern, the via-filling part and the second circuit pattern are formed of metal paste or conductive paste.

9. A heat radiating substrate comprising:
a substrate having a via-hole;
an anode oxide layer formed on the entire surface of the substrate having the via-hole through an anodizing process;
a first circuit pattern formed on the substrate on which the anode oxide layer is formed; and
a second circuit pattern formed at a lower part of the via-hole to be connected to the via-hole, wherein the first circuit pattern is adhered to the substrate, on which the anode oxide layer is formed, through anodic bonding.

10. The heat radiating substrate according to claim 9, wherein the via-hole is formed to at least two or more.

11. The heat radiating substrate according to claim 9, wherein the via-hole is filled with metal paste or conductive paste.
